(19) United States
(12) Patent Application Publication
(10) Pub. No.: US 2022/0317642 A1
(43) Pub. Date: Oct. 6, 2022

(54) A MODULAR CONTROLLER FOR DIFFERENT INPUT SIGNALS, AN ASSEMBLY METHOD OF THE SAID CONTROLLER AND A METHOD FOR ENERGY MANAGEMENT USING THE SAID CONTROLLER

(71) Applicant: AMIBIT D.O.O., Velenje (SI)

(72) Inventors: Tadej BERAVS, Trbovlje (SI); Primoz BECAN, Ljubljana (SI); Ales NASTRAN, Velenje (SI); Mitja RUZZIER, Log pri Brezovici (SI)

(21) Appl. No.: 17/620,509

(22) PCT Filed: Jun. 18, 2020
(86) PCT No.: PCT/SI2020/050016

§ 371 Date: Dec. 17, 2021

(30) Foreign Application Priority Data
Jun. 19, 2019 (SI) P-201900121

(51) Int. Cl. G05B 19/042

(52) U.S. Cl. CPC G05B 19/042; G05B 2219/2639

(57) ABSTRACT

The present invention belongs to the field of control systems, in particular controllers of different processes. The invention relates to a modular controller for energy management, which can be adapted with regards to the manager's needs. The invention additionally relates to a method of modular assembly for different input signals as well as a method of energy management using the said controller. The essence of the invention is in that the controller has a housing inside which nine empty slots are provided; said slots may be equipped with arbitrary components with regards to the system to be controlled with the controller. Said empty slots may be provided with one or more of the following components such as relay, digital output, digital input, analogue output, analogue input, optically separated input, reading current signal, reading temperature sensor, etc. The controller may control usage or manufacture of gases, electricity and/or heat.

### FIELD OF THE INVENTION

The present invention belongs to the field of control systems, in particular controllers of different processes. The invention also belongs to the field of energy management. The invention relates to a modular controller for energy management, which can be adapted with regards to the manager's needs. The invention additionally relates to a method of modular assembly for different input signals as well as a method of energy management using the said controller.

### Background of the Invention and the Technical Problem

System for energy management is a common name for all activities that affect energy use and costs connected with it. The system comprises devices or elements, which include among other functions overview of energy consumption and/or adjustment of other components of the system, so that consumption of energy may be optimized.

Overview and adjustment of energy consumption functions may be performed with processing controllers, which are essentially programmable circuits with digital/analogue inputs, power digital outputs and communication modules. They are programmed in a suitable programming environment installed on a computer and later functional autonomously. They are used in different applications, including for automatization of manufacturing processes, regulation of physical quantities such as temperature, moisture, pressure, water level and similar. The basic components of such control systems are:
programmable logical controller (PLC),
sensors for monitoring,
an actuator, which can affect the PLC and subsequently the process based on the information provided by sensors,
program tools with system or mechanism logic, needed for control and transfer to the memory unit of the PLC as well as for launching the controller,
a memory unit, and
a display and control units that enable tracking and adjusting of system/mechanism operation.

The PLC is connected with the system to be controlled via input and output modules. The system to be controlled gives input signals via sensors to input modules. These signals are processed in the main processing unit, which is the main component of the PLC. Input signals comprise information about the status of the controlled system. Output signals on the other hand affect the system to be controlled. The said signals may be digital or analogue. Such commercially available controllers have been described in patent EP 0 352 683.

The described controllers are usually composed of a fixed number of particular input and output modules, so that many free spaces remain unoccupied or a user has to use several different controllers in order to have a sufficient number of, for example, digital inputs or analogue outputs. This consequently results in space consumption as well as in increase the costs of the process. The technical problem, which is solved by the present invention, is thus a design of a process controller suitable for energy management that will allow adjustment of components mounted inside the controller's housing.

### STATE OF THE ART

Patent EP 0 490 864 B1 describes a controller of a process, wherein the controller comprises a processor, a plurality of connectors, means for electrical connection of connectors to the processor and a plurality of input and output modules. The controller has a removably connected one digital input, one digital output, one analogue input and one analogue output. Said controller also comprises means for automatic setting of the type of input and output modules, wherein all components are installed inside a housing of the controller.

The same document describes a communication method in the controller, which comprises the following steps:
a) transferring a command from the processor to one of the modules,
b) receiving the signal from the module as a response to the command in step a)
c) setting the type of the module based on the signal in step b), which may be a digital input, a digital output, an analogue input or an analogue output
d) based on the type of the module, communication of suitable value (analogue or digital) to the module, and
e) repeating the above-mentioned steps.

Controllers belonging to series System Q produced by Mitsubishi electric offer a concept that enables the user to compose an optimal combination of CPU, communication interfaces, special control modules and discrete V/I units on the base housing of the controller. The latter enables configuration of the system with regards to the application every time. The selected example shows a classic configuration of industrial controllers, i.e. a basic controller to which expansion units/modules are added, however, the added units or modules are always added in full size. Hence, in case only 1 discrete input is needed, this solution requires from the user to buy and add a whole unit of discrete inputs (usually comprising 16 in one unit/modules), which is then installed besides the controller. The size of the controller is consequently enlarged and additionally, also the costs of such controllers are increased.

### Description of the Solution of the Technical Problem

The invention is a multipurpose modular controller for management and connection of devices or sensors into a central online system with use of symmetrically and asymmetrically encrypted connection, preferably using a suitable certificate and a 2048 or 4096 byte encoding key. The essence of the invention is in that the controller has a housing inside which nine empty slots are provided, which can be equipped with arbitrary components with regards to the system to be controlled with the controller. Said empty slots inside the basic part or the housing of the controller can be provided with one or more of the following components (expansion cards) in any combination:
relay,
digital output,
analogue output,
digital input,
analogue input,
optically separated digital input,
means for reading a current signal, and
means for reading a temperature sensor.

The key difference in comparison to known solution is in that the controller according to the invention enables addition of discrete inputs inside the basic part of the controller so that no additional exterior units are needed. The controller according to the invention cannot recognize the type of the inserted card on its own, as this is set up during configuration of the controller via an online interface. The controller is automatically connected into a cloud system using its own software using safety certificates, wherein the data transfer technology via a mobile network GPRS, 3G, LTE, internet via LAN connection or wireless internet. When a user registers, he gains access to the cloud system and may begin with setting and parameterization the controller by providing the unique number of the controller.

Each of the expansion cards in the controller has two types of connectors, which may be connected to connectors on empty slots in the controller. The first type is a connector that connects a controlled device with the electronics on the expansion card. The other type of the connector is a universal connector that enables communication between the expansion card and the basic plate (main board). The information from the cloud or a computer server comes via the first connector to the expansion card, where the information is suitable transformed (for example into a discrete/continuous signal, high-energy signal, temperature, etc. . . . ) and is sent via the second connector to the base plate. From there is information is transferred to the processing module, where said module uses the information for further processing. The signalling pathway may also be vice-versa, wherein the processing module gives a command to the base plate, the latter sends the command to the expansion card and this card makes a suitable response (for example makes a connection), which for the controlled devices means that a certain action has to be performed, such as turning on light or igniting a furnace. The communication between an expansion card and the base plate is possible via usual discrete signals or via a higher-level communication.

In general, the controller has a housing, inside which the following components are provided:
a base plate,
a processor,
a power supply for ensuring energy for controller operation,
means for ensuring network connection,
a USB connector for connecting expansion modules and/or communication modules,
an unit for connection with a computer server or a cloud comprising a program for controlling and programming the controller, for processing signals/data and controlling energy consumption,
   wherein any following components in an combination may be connected to the base plate:
communication interfaces,
expansion cards (relay, digital output, digital input, analogue output, analogue input),
communication module M BUS for communication between different devices, which are controlled by the controller,
a mobile module such as GSM or LTE for connection to the cloud or server, and
a computer module.

Main advantages of the described controller are high safety due to data coding, preferably using symmetrical and asymmetrical coding, modular and flexible design, easy connection and simple use. The controller preferably operates in a cloud via suitable servers, while communication is carried out via mobile network. All settings and algorithms of the controller are stored in a cloud and that during an optional controller replacement the user has to enter a unique number of the existing controller from which the settings and operation algorithms are automatically transferred to a new controller.

A method for assembly of the controller according to the invention is carried out in the following way: to at least one, preferably each, of the nine empty slots in the upper part of the controller a selected expansion card is inserted, wherein the said expansion card is used for control and management of a particular electrical signal. The cards may be inserted modularly in the bottom part of the controller into connectors, which are primarily intended for communication cards and serve as connection into the control system via the mobile network and for transforming electrical signals for different communication protocols such as M-bus, DALI, KNX, etc. . . . . All cards are inserted into the controller by simple pressing of the expansion card into the base plate without any tool. The identity of cards and their function is programmed in the online system.

The method for energy management with the modular controller according to the invention is carried out in the following way: that the modular controller with selected expansion cards is prepared with regards to connected devices, which will be controlled with the controller. The method of energy management also includes programming of the controller; following different signals and sensors, via which the controller obtains information regarding the current state of energy consumption and adjusts operation of devices with regards to pre-set parameters and/or pre-set schedules and/or environmental conditions.

The purpose of the controller is controlling different signals and sensors, which provide information about the current state of energy consumption, as well as adjustment of energy consumption with regards to pre-set parameters, schedules or external conditions. Expansion cards may be selected and combined arbitrarily, wherein the cards perform the following tasks:
relay operates as electronically controlled switch for turning on different devices such as heaters, lights and similar;
digital output operates as a low-energy electrical signal for turning on smaller burdens;
analogue output enables continuous control of certain devices, most commonly electrically powered valve for heat conduits, wherein the continuous control is enabled with a definition of voltage or current in a particular range, which in turn means a particular state of the valve (open, close, and values in-between);
digital input is for reading electrical signals of lower voltage, particularly for reading meters of different energy sources;
optically separated input for reading voltage presence, which gives an information about device status, pump status or device error;
reading a current signal from 4 to 20 mA for reading different industrial sensors, such as reading pressure, moisture, temperature values, etc.;
reading a temperature sensor enables reading ambient temperature or water temperature.

Because the controller is connected to the internet, it may use data for different forecasts (for example weather, wind, etc. . . . ) based on which the controller adapts operation and optimizes energy consumption. All settings of parameters and programming of the controller is carried out locally or remotely via a mobile interface. The controller ensures monitoring of usage of all types of energy such as electricity, gas, heat, heating oil, steam and similar, and controlling of different devices that consume energy with the aim of consumption optimization such as furnaces, heat pumps, pipe conduits, radiators, convectors, ventilation units, refrigeration units, lighting units, electric heaters, and the like.

The controller is connected to the central control system with high coding standards using symmetrical and asymmetrical coding and usage of 2048 or 4096 byte encrypted key, which means that the system does not need its own APN (Access Point Name). All settings and controller algorithms are saved in the cloud, which in case of controller replacement allows automatic transfer of all settings by providing the unique number of the preceding controller. In contrast, the system for existing controllers is stored at a local computer, wherein in case of controller replacement, the program has to be transferred to the new controller, which may complicate the replacement procedure, as the program may be out-of-date or may not be working correctly, or similar.

The invention will be described in further detail based on exemplary embodiments and figures, which show:

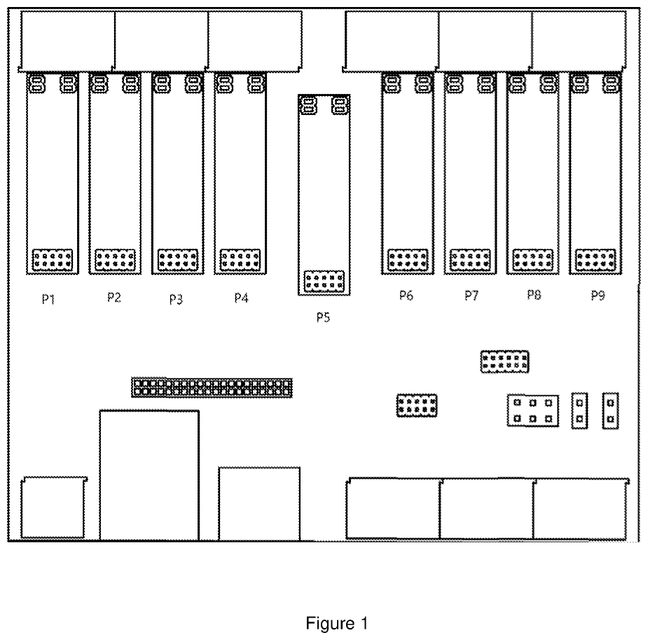

FIG. 1 Interior of the controller with shown positions for expansion cards

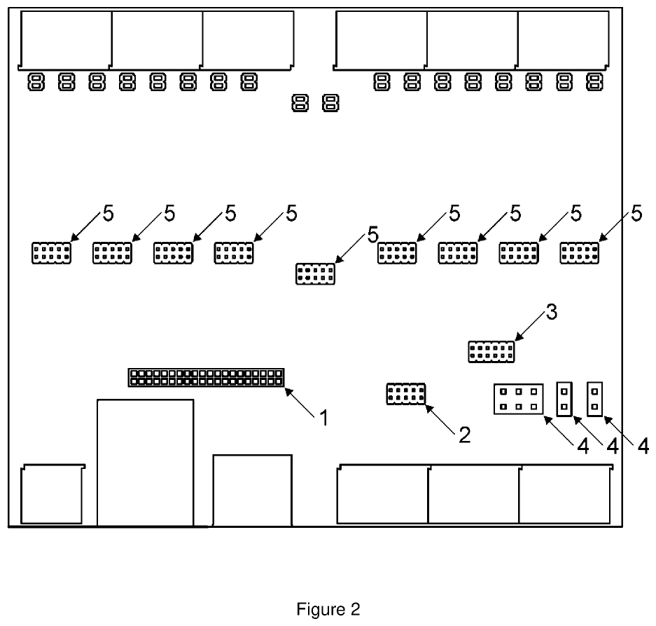

FIG. 2 Interior of the controller with shown positions of connectors

The controller according to a possible embodiments comprises two basic components, namely a base plate as shown in FIG. 1 and a computer module, wherein the base plate (base plate) enables connection of further expansions such as mobile (GSM, LTE, LTE-NB, and similar), M-BUS communication and input/output expansion cards. The computer module controls all modules and expansion cards, as a suitable program (software) for management of tasks related to energy management is run on the computer module. FIG. 2 shows the interior of the controller according to the embodiment, wherein the positions of connectors are the following:
1 40-pin connector for the computer module
2 10-pin connector for M-BUS
3 12-pin connector for a mobile (GSM) modem
4 10-pin socket—reserve
5 9×10-pin connector for expansion cards

The empty slots in the housing of the controller may be equipped with at least one or more of the following components, depending on the system to be controlled with the controller. Selection is made among the following components in arbitrary numbers and combinations:
relay, with switching option at 230 V at 3 A, operates as electronically controlled switch for turning on different devices such as heaters, lights and similar;
digital output—2× output of the current voltage, which functions as a low-energy electrical signal for turning on smaller burdens;
analogue output for setting output voltage from 0 to 10 V DC or current from 4 to 20 mA, which enables continuous control of certain devices, most commonly electrically powered valve for heat conduits, wherein the continuous control is enabled with a definition of voltage or current in a particular range, which in turn means a particular state/position of the valve (open, close, and values in-between, for example ¾ open);
digital input −2× reading of voltage up to 24 V for reading electrical signals of lower voltage, particularly for reading meters of different energy sources;
optically separated input—reading of voltage up to 230 V AC, 24 V DC or 12 V DC for reading voltage presence, for example to determine if a furnace is working or a pump is turned on, or if any device has an error, etc.;
reading a current signal from 4 to 20 mA for reading different industrial sensors, such as reading pressure, moisture, temperature values, etc.;
reading a temperature sensor PT1000 or PT100 for reading ambient temperature or water temperature, etc.

The controller may manage individual functions or a combination of the following:
usage or manufacture of gases by reading data from gas meters of different manufacturers (pulse, RS232, RS484, M-bus, Modbus, KNX, . . . ); and/or
usage or manufacture of electricity by reading data from electric meters of different manufacturers (pulse, RS232, RS484, M-bus, Modbus, KNX, . . . ); and/or
usage or manufacture of heat by reading data from calorimeters of different manufacturers (pulse, RS232, RS484, M-bus, Modbus, KNX, . . . ).

Further, the modular controller may control operation of furnaces, lights, heaters and similar devices based on known conditions in a building or based on weather forecast. The controller and the method for energy management with the said controller enables control of operation of all energy devices and automated energy bookkeeping, so that energy consumption is optimized.

1. A modular controller for energy management, particularly for management and connection of devices or sensors in a central system, characterized in that the interior of a housing of the controller is provided with nine empty slots, which may be equipped with arbitrary components with regards to requirements of the system for energy management to be controlled with the controller, wherein the said empty slots may be equipped with one or more expansion cards in any combination:
relay,
digital output,
analogue output,
digital input,
analogue input,
optically separated digital input,
means for reading current signal, and
means for reading a temperature sensor;
wherein the controller enables addition of discrete units/cards inside the base part of the controller.

2. The modular controller according to claim 1, characterized in that the controller does not recognize the type of card inserted to an empty slot, but the said type is set during controller configuration via an online interface.

3. The modular controller according to claim 1 or claim 2, characterized in that the controller comprises the housing, inside which the following is provided:
a base plate,
a processor,
a power unit for ensuring energy supply for operation of the controller,
means for ensuring network connection,
an USB connector for connecting expansion modules and/or communication modules,
a connection unit for connection with a computer server or a cloud, where a program for controlling and programming the controller, for processing signals/data and controlling energy management is run,
wherein any following components in an combination may be connected to the base plate:
communication interfaces,
expansion cards (relay, digital output, digital input, analogue output, analogue input),
communication module M BUS for communication between different devices, which are controlled by the controller,
a mobile module such as GSM or LTE for connection to the cloud or server, and
a computer module.

4. The modular controller according to any of the preceding claims, characterized in that each of the said expansion cards in the controller has two types of connectors, which may be connected to connectors at empty slots in the controller, wherein:
the first connector type is a connector that connects a controlled device with the electronics on the expansion card, and
the second connector type is a universal connector that enables communication between the expansion card and the base plate.

5. The modular controller according to any of the preceding claims, characterized in that expansion cards in arbitrary combinations inside the controller perform the following tasks:
relay operates as electronically controlled switch for turning on different devices such as heaters, lights and similar;
digital output operates as a low-energy electrical signal for turning on smaller burdens;
analogue output enables continuous control of certain devices, most commonly electrically powered valve for heat conduits, wherein the continuous control is enabled with a definition of voltage or current in a particular range, which in turn means a particular state of the valve (open, close, and values in-between);
digital input is for reading electrical signals of lower voltage, particularly for reading meters of different energy sources;
optically separated input for reading voltage presence, which gives an information about device status, pump status or device error;
reading a current signal from 4 to 20 mA for reading different industrial sensors, such as reading pressure, moisture, temperature values, etc.;
reading a temperature sensor enables reading ambient temperature or water temperature.

6. The modular controller according to any of the preceding claims, characterized in that it comprises the following components:
relay, with switching option at 230 V at 3 A, operates as electronically controlled switch for turning on different devices such as heaters, lights and similar;
digital output, which functions as a low-energy electrical signal for turning on smaller burdens;
analogue output for setting output voltage from 0 to 10 V DC or current from 4 to 20 mA, which enables continuous control of certain devices;
digital input for reading electrical signals of lower voltage, particularly for reading meters of different energy sources;
optically separated input for reading of voltage up to 230 V AC, 24 V DC or 12 V DC for reading voltage presence such as control of operation;
reading a current signal from 4 to 20 mA for reading different industrial sensors, such as reading pressure, moisture, temperature values, etc.; and
reading a temperature sensor PT1000 or PT100 for reading ambient temperature or water temperature, etc.

7. The modular controller according to any of the preceding claims, characterized in that the controller performs monitoring of usage of all types of energy such as electricity, gas, heat, heating oil, steam and similar, and also performs controlling of different devices that consume energy with the aim of consumption optimization such as furnaces, heat pumps, pipe conduits, radiators, convectors, ventilation units, refrigeration units, lighting units, and electric heaters.

8. The modular controller according to any of the preceding claims, characterized in that it controls individual functions or a combination of the following:
usage or manufacture of gases by reading data from gas meters; and/or
usage or manufacture of electricity by reading data from electric meters; and/or
usage or manufacture of heat by reading data from calorimeters.

9. The modular controller according to any of the preceding claims, characterized in that all settings and algorithms of the controller are stored in a cloud and that during an optional controller replacement the user has to enter a unique number of the existing controller from which the settings and algorithms are automatically transferred to a new controller.

10. The modular controller according to any of the preceding claims, characterized in that the controller is connected to the online system by using symmetrical and asymmetrical encrypted connection, preferably by using a suitable certificate and 2048 or 4096 byte encryption key.

11. An assembly method of the controller according to any of the preceding claims, the method comprising the following steps:
to at least one, preferably each of the nine empty slots in the upper part of the controller a selected expansion card is inserted, wherein the said expansion card is used for control and management of a particular electrical signal, wherein the cards may also be inserted modularly in the bottom part of the controller into connectors, which are primarily intended for communication cards and serve as connection into the control system via the mobile network and for transforming electrical signals for different communication protocols;
all cards are inserted into the controller by simple pressing of the expansion card into the base plate; and
the identity of cards and their function is programmed in the online system.

12. A method of energy management with the modular controller according to any claim from 1 to 10, the said method comprising the following steps:
assembly of the modular controller with selected expansion cards with regards to connected devices, which will be controlled with the controller;
programming of the controller;
following different signals and sensors, via which the controller obtains information regarding the current state of energy consumption;
adjusting operation of devices with regards to pre-set parameters and/or pre-set schedules and/or environmental conditions.
